(19) United States
(12) Patent Application Publication
(10) Pub. No.: US 2008/0170371 A1
(43) Pub. Date: Jul. 17, 2008

(54) Combination assembly of led and heat sink

(75) Inventor: Yaw-Huey Lai, Taipei County (TW)

Correspondence Address: BACON & THOMAS, PLLC, 625 SLATERS LANE, FOURTH FLOOR, ALEXANDRIA, VA, 22314, US

(73) Assignee: TAI-SOL ELECTRONICS CO., LTD., TAIPEI CITY (TW)

(21) Appl. No.: 11/790,525

(22) Filed: Apr. 26, 2007

(30) Foreign Application Priority Data
Jan. 12, 2007 (TW) 96200703

(51) Int. Cl. H05K 7/20

(52) U.S. Cl. 361/720

(57) ABSTRACT

A combination assembly of LED and heat sink includes a heat sink having a substrate and a plurality of fins, a circuit board provided on the substrate and at least one LED unit provided on the heat sink and electrically connected to the circuit board. The heat of the LED unit may be transmitted to the heat sink directly for heat transmission. The present invention has a greater heat transmission efficiency.

### BACKGROUND OF THE INVENTION

1. Field of the Invention

The present invention relates generally to a light emitting diode (LED), and more particularly to a combination assembly of LED and heat sink, which has a greater performance in heat transmission.

2. Description of the Related Art

In present days, the high luminance LED produces high heat, and there is no fine solution to fix it yet.

U.S. Pat. No. 5,173,839 provides a heat transmission technique of a LED display. It provides a stack of a belt, an aluminum block, a belt and a heat sink under a LED chip to transmit the heat out. However, this technique provides three intermediates between the LED chip and the heat sink, which is the one performing heat transmission, that make the heat transmission rate is poor because the intermediates cause a greater heat resistance.

Taiwan Patent no. M295889 provides another heat transmission technique of LED. It provides a LED on a heat pipe. The LED includes a LED plastic insulating circuit board, a LED chip base, a LED heat chip and a LED lens. However, this technique provides the heat pipe, which has a high efficiency of heat transmission, to be the main for heat transmission, but there are also intermediates, the LED chip base and the LED plastic insulating circuit board, therebetween. These intermediates also cause the problem of high heat resistance and low heat transmission rate.

### SUMMARY OF THE INVENTION

The primary objective of the present invention is to provide a combination assembly of LED and heat sink, which has a greater heat transmission performance for the LED.

According to the objective of the present invention, a combination assembly of LED and heat sink includes a heat sink having a substrate and a plurality of fins, a circuit board provided on the substrate and at least one LED unit provided on the heat sink and electrically connected to the circuit board. The heat of the LED unit may be transmitted to the heat sink directly for heat transmission. The present invention has a greater heat transmission efficiency.

### BRIEF DESCRIPTION OF THE DRAWINGS

FIG. 1 is a perspective view of a first preferred embodiment of the present invention;

FIG. 2 is a top view of the first preferred embodiment of the present invention;

FIG. 3 is a sectional view along the 3-3 line of FIG. 2;

FIG. 4 is a sectional view of a second preferred embodiment of the present invention;

FIG. 5 is a sectional view of a third preferred embodiment of the present invention; and

FIG. 6 is a sectional view of the third preferred embodiment of the present invention, showing another package device.

### DETAILED DESCRIPTION OF THE INVENTION

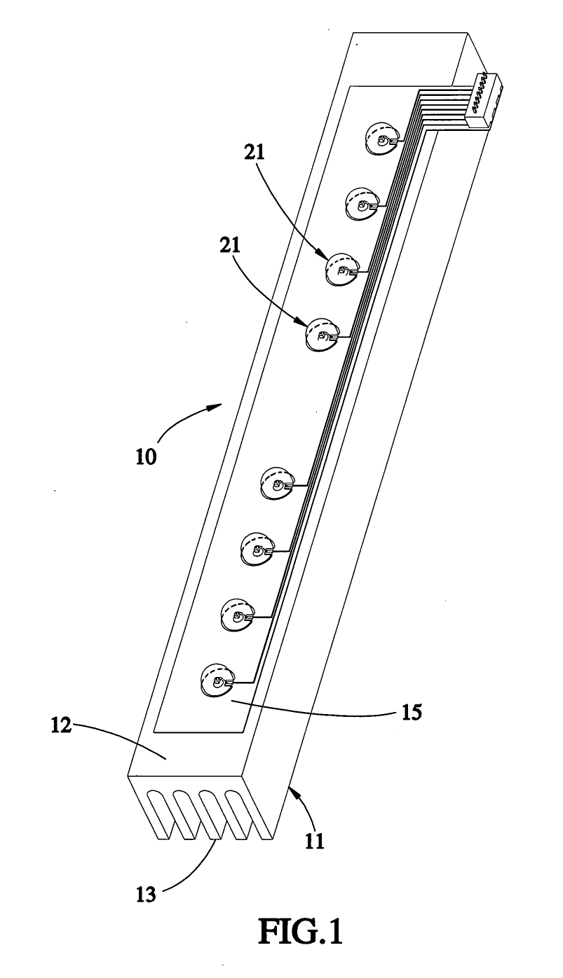

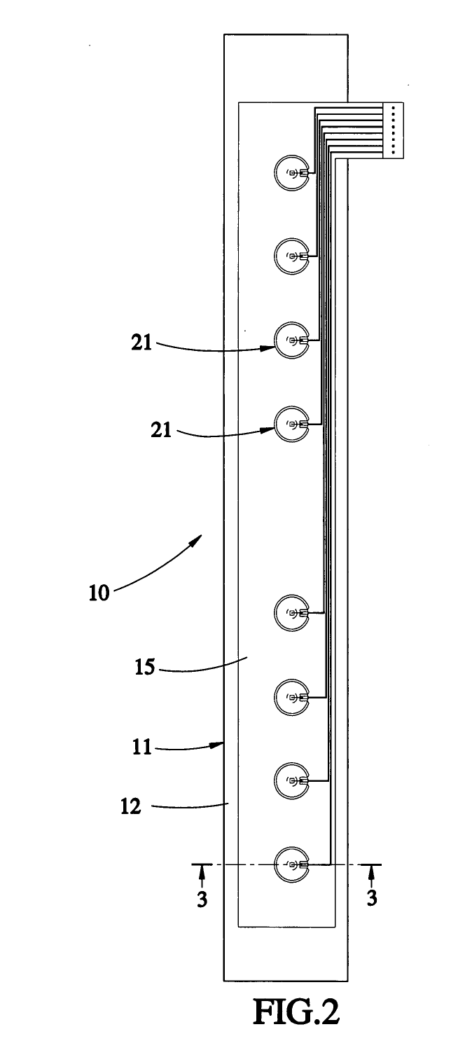

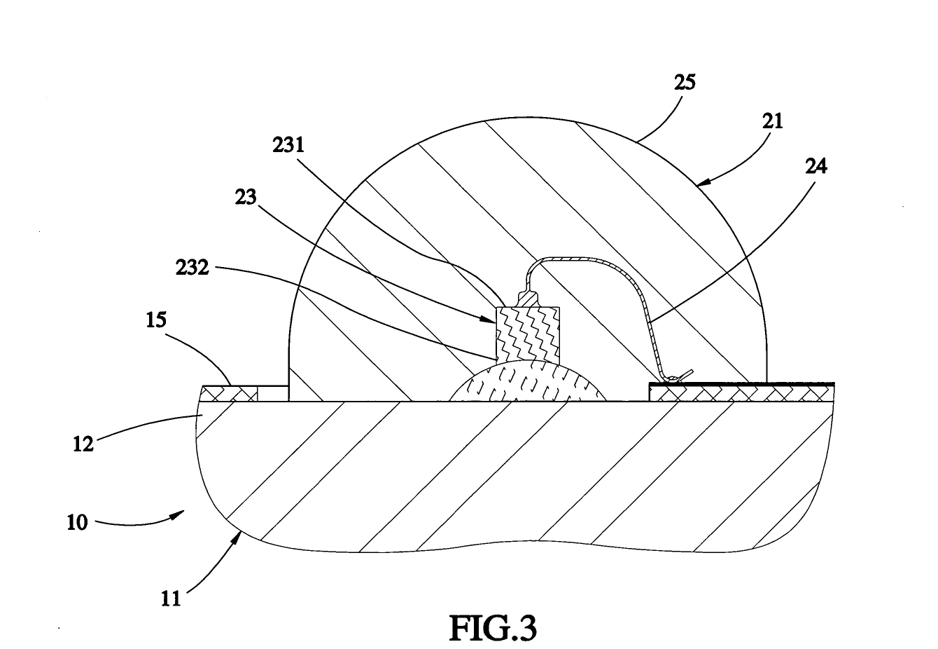

As shown in FIG. 1 to FIG. 3, a combination assembly of LED and heat sink 10 of the first preferred embodiment of the present invention mainly includes a heat sink 11, a circuit board 15 and a plurality of LED units 21.

The heat sink 11 includes a substrate 12 and a plurality of fins 13.

The circuit board 15 is mounted on the substrate 12.

The LED units 21 are mounted on the substrate 12 and electrically connected to the circuit board 15. Each of the LED units 21 mainly includes a LED chip 23, a wire 24 and a package device 25. The LED chip 23 has an anode 231 and a cathode 232. The cathode 232 is connected to the substrate 12. The wire 24 has an end connected to the anode 232 of the LED chip 23 and the other end connected to the circuit board 15. The package device 25 is an encapsulant, which is transparent or semi-transparent doped with fluorescence powder, encapsulating the LED chip 23 and the wire 24.

In practice operation of the first embodiment, an electronic driving device is connected to the circuit board 15 and the substrate 12. The cathodes 232 of the LED chips 23 are electrically connected to the substrate 12 through the wire 24 to form a common cathode that an electrical circuit board is formed. A power supply (not shown) is connected to the LED chips 23 through the wire 24 and the substrate 12 to make them lighting. A heat, which is generated by the LED chips 23 when they are lighting, will be transmitted to the substrate directly, and then transmitted to the fins 13 for heat transmission by the heat sink 11 with a grater size. This provides a high heat transmission efficiency for the LED chips 23.

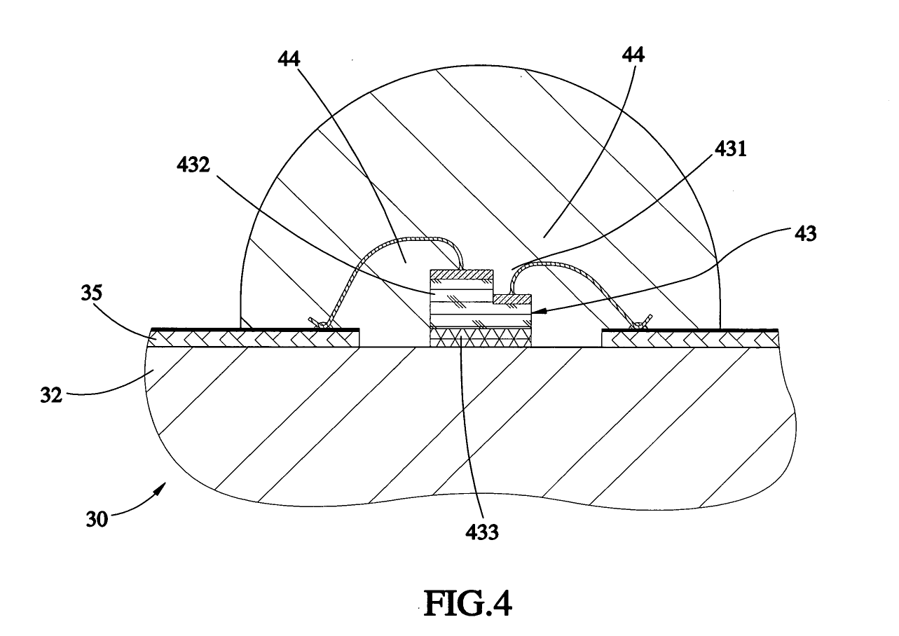

As shown in FIG. 4, a combination assembly of LED and heat sink 30 of the second preferred embodiment of the present invention, which is similar to the assembly 10 of the first embodiment, except that:

Each of LED chips 43 has an anode 431 and a cathode 432 at a top thereof and has an insulating layer 433 at a bottom thereof. The anode 431 and the cathode 432 are electrically connected to the circuit board 35 through a wire 44.

The main difference between the second embodiment and the first embodiment is the LED chips 43 and how they mounted on the substrate 32. Except that, the rest structure, operation mode and functions of the second embodiment are as same as the first embodiment, and we will not describe it again.

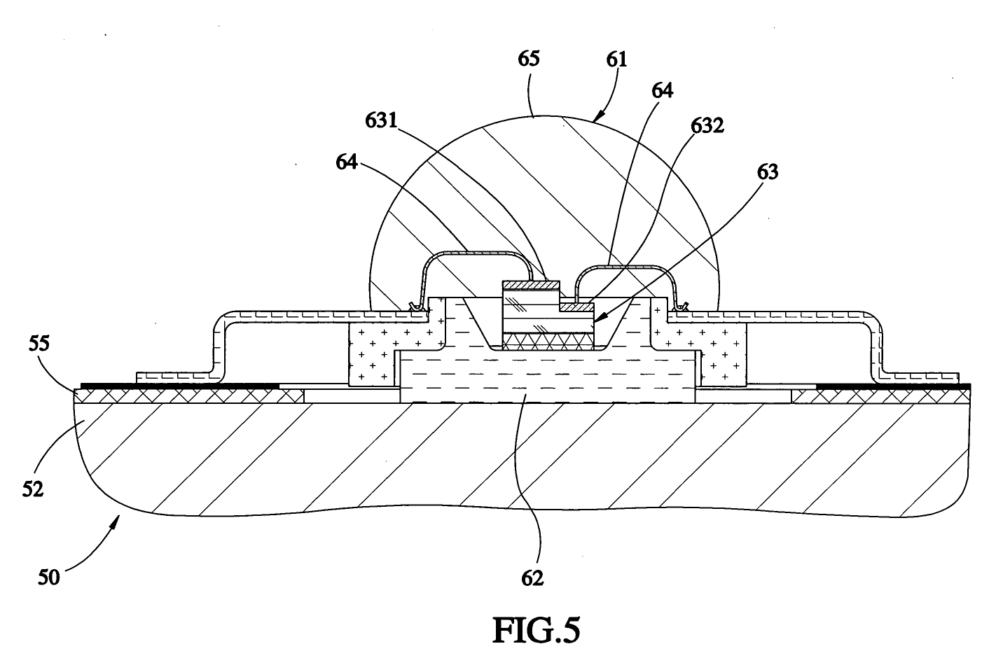

As shown in FIG. 5, a combination assembly of LED and heat sink 50 of the third preferred embodiment of the present invention, which is similar to the assembly 10 of the first embodiment, except that:

Each of LED units 61 has a heat transmission base 62, a LED chip 63, two wires 64 and a package device 65. The heat transmission base 62 is mounted on a substrate 52, and the LED chip 63 is mounted on the heat transmission base 62. The wires are connected to an anode 631 and a cathode 632 of the LED chip 63 and a circuit board 55 respectively. The package device 65 encapsulates the LED chip 63, the wires 64 and the heat transmission base 62 therein.

The main difference between the third embodiment and the first embodiment is the LED chips 63, which has the heat transmission base 62 to be mounted on the substrate 52. Except that, the rest structure, operation mode and functions of the third embodiment are as same as the first embodiment, and we will not describe it again.

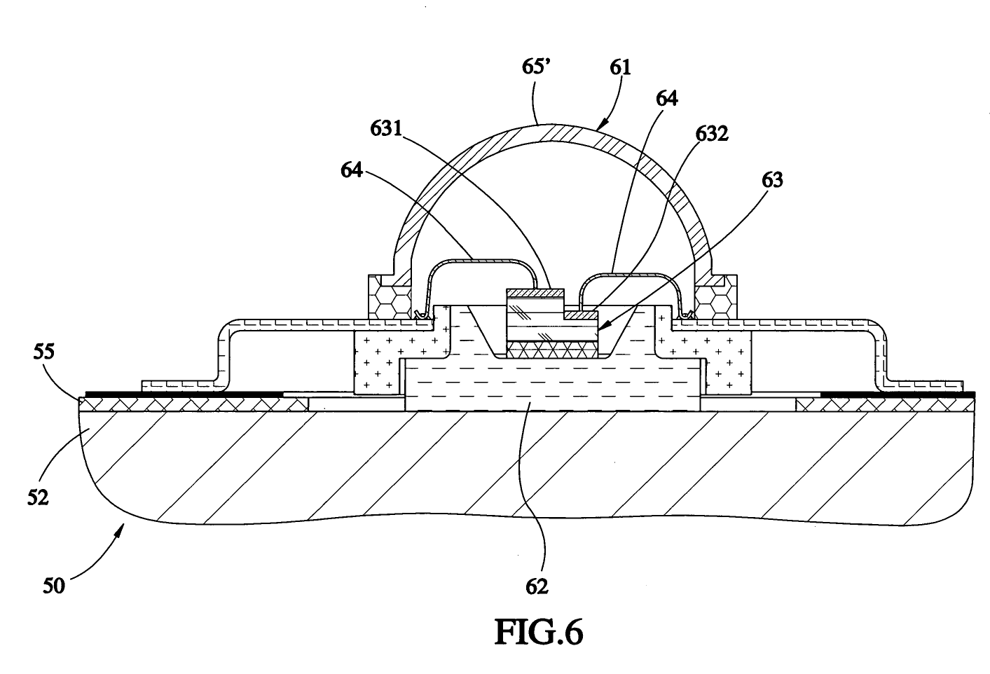

In addition, the third embodiment also may provide a lid-like package device 65′, as shown in FIG. 6, which has the same function of the encapsulant package device as described above.

In conclusion, the advantages of the present invention are:

Higher performance of heat transmission: to compare with the prior art, the present invention has no intermediate between the LED chips and the heat sink, so that the present invention has less heat transmission resistance. The present invention provides the LED chips mounted on the heat sink directly or provides a heat transmission base, which has a high heat transmission efficiency, between the LED chips and the heat sink that the heat of the LED chips may be transmitted to the heat sink directly or through the heat transmission base for heat transmission by the great size of the heat sink that has a greater performance of heat transmission than the prior art.

The description above is a few preferred embodiments of the present invention and the equivalence of the present invention is still in the scope of the claim of the present invention.

What is claimed is:

1. A combination assembly of LED and heat sink, comprising:
a heat sink including a substrate and a plurality of fins;
a circuit board provided on the substrate; and
at least one LED unit provided on the heat sink and electrically connected to the circuit board.

2. The combination assembly of LED and heat sink as defined in claim 1, wherein there are two or more LED units, each of which includes a LED chip provided on the substrate, at least one wire having opposite ends connected to the LED chip and the circuit board respectively and a package device encapsulating the LED chip and the wire.

3. The combination assembly of LED and heat sink as defined in claim 2, wherein the LED chip has an anode connected to the wire and a cathode connected to the substrate.

4. The combination assembly of LED and heat sink as defined in claim 2, wherein the LED chip has an anode and a cathode at a top thereof and an insulating layer on a bottom thereof, wherein the insulating layer is mounted on the substrate, and the anode and the cathode are electrically connected to the circuit board through two of the wires.

5. The combination assembly of LED and heat sink as defined in claim 1, wherein there are two or more LED units, each of which includes a heat transmission base, a LED chip provided on the heat transmission base, two wires having opposite ends connected to an anode and a cathode of the LED chip and the circuit board respectively and a package device encapsulating the LED chip and the wire.

6. The combination assembly of LED and heat sink as defined in claim 2, wherein the package device is an encapsulant.

7. The combination assembly of LED and heat sink as defined in claim 5, wherein the package device is an encapsulant.

8. The combination assembly of LED and heat sink as defined in claim 1, wherein the package device is a lid.
